(19) United States
(12) Patent Application Publication
(10) Pub. No.: US 2023/0380059 A1
(43) Pub. Date: Nov. 23, 2023

(54) MODULE

(71) Applicant: Murata Manufacturing Co., Ltd., Kyoto-fu (JP)

(72) Inventors: Yoshihito OTSUBO, Nagaokakyo-shi (JP); Takamitsu NAKAMURA, Nagaokakyo-shi (JP)

(21) Appl. No.: 18/363,790

(22) Filed: Aug. 2, 2023

Related U.S. Application Data
(63) Continuation of application No. PCT/JP2021/047546, filed on Dec. 22, 2021.

(30) Foreign Application Priority Data
Feb. 5, 2021 (JP) 2021-017287

(51) Int. Cl. H05K 1/02

(52) U.S. Cl. CPC H05K 1/0298; H05K 1/0256; H05K 2201/093

(57) ABSTRACT

A module includes a substrate including a first surface, a first land electrode arranged on the first surface, and a first electronic component mounted on the substrate with the first land electrode being interposed. The substrate is provided with a first opening that passes through the substrate in a direction of thickness within a projection area of the first land electrode.

### CROSS REFERENCE TO RELATED APPLICATION

This is a continuation of International Application No. PCT/JP2021/047546 filed on Dec. 22, 2021 which claims priority from Japanese Patent Application No. 2021-017287 filed on Feb. 5, 2021. The contents of these applications are incorporated herein by reference in their entireties.

### BACKGROUND OF THE DISCLOSURE

### Field of the Disclosure

The present disclosure relates to a module.

### Description of the Related Art

U.S. Pat. No. 10,418,341 B2 (PTL 1) discloses a construction in which various components are mounted on a surface of a substrate.
PTL 1: U.S. Pat. No. 10,418,341 B2

### BRIEF SUMMARY OF THE DISCLOSURE

A module has increasingly been reduced in size and higher in density. Consequently, a gap between components at the time of mounting has become narrower. With reduction in size of the component, a gap between terminal electrodes has also become narrower. Possibility of short-circuiting between electrodes or between solder bumps has thus become higher.

In mounting components on a motherboard, such a form as initially mounting the components on a wiring board to make one package and then mounting this package on the motherboard may be adopted. When such a method is adopted, however, presence of the wiring board leads to a high profile of the package. There is also such a form as a coreless package not requiring a wiring board. In the package, an IC mounted with a bump being interposed, a component mounted with an LGA being interposed, or a component mounted with a side surface electrode being interposed may be provided. Components different in form of mounting may also be present in one package.

In the case of the coreless package, electrodes are exposed at a lower surface of the package. When there are components different in form of mounting, electrodes exposed at the lower surface of the package are in various forms such as a bump, an LGA, or a side surface electrode, and an area of each exposed electrode is greatly different depending on the form of the electrode. Therefore, mounting of such a coreless package on a motherboard with solder tends to cause excess or shortage in amount of applied solder, and such a problem as short-circuiting between portions not to be connected to each other or failure in connection between portions to be connected to each other may arise. In other words, mounting is unstable.

A possible benefit of the present disclosure is to provide a module capable of achieving suppression of short-circuiting in mounting thereof on a motherboard or the like and achieving stable mounting.

In order to achieve the possible benefit, a module based on the present disclosure includes a substrate including a first surface, a first land electrode arranged on the first surface, a first electronic component mounted on the substrate with the first land electrode being interposed, and an insulating film that partially covers the first land electrode. The substrate is provided with a first opening that passes through the substrate in a direction of thickness within a projection area of the first land electrode, the first electronic component is electrically connected to the first land electrode in an exposed area in the first land electrode exposed without being covered with the insulating film, and the first opening is larger than the exposed area.

According to the present disclosure, at the time of mounting, a conductive material can be accommodated in the first opening and there is no overflow of the conductive material therearound. Therefore, short-circuiting in mounting on a motherboard or the like can be suppressed and mounting can be performed in a stable manner.

### BRIEF DESCRIPTION OF THE SEVERAL VIEWS OF THE DRAWINGS

FIG. 1 is a perspective view of a module in a first embodiment based on the present disclosure.

FIG. 2 is a cross-sectional view of the module in the first embodiment based on the present disclosure.

FIG. 3 is a cross-sectional view along the line III-III in FIG. 2.

FIG. 4 is a bottom view of the module in the first embodiment based on the present disclosure.

FIG. 5 is a cross-sectional view of a module in a second embodiment based on the present disclosure.

FIG. 6 is a bottom view of the module in the second embodiment based on the present disclosure.

FIG. 7 is a cross-sectional view along the line VII-VII in FIG. 5.

FIG. 8 is a cross-sectional view of a module in a first modification of the second embodiment based on the present disclosure.

FIG. 9 is a bottom view of the module in the first modification of the second embodiment based on the present disclosure.

FIG. 10 is a cross-sectional view along the line X-X in FIG. 8.

FIG. 11 is a cross-sectional view of a second modification of the second embodiment based on the present disclosure.

FIG. 12 is a cross-sectional view of a module in a third embodiment based on the present disclosure.

FIG. 13 is a cross-sectional view along the line XIII-XIII in FIG. 12.

FIG. 14 is a bottom view of the module in the third embodiment based on the present disclosure.

FIG. 15 is a cross-sectional view of the module in the third embodiment based on the present disclosure, as being mounted on a motherboard.

FIG. 16 is a cross-sectional view of a module in a fourth embodiment based on the present disclosure.

FIG. 17 is a bottom view of the module in the fourth embodiment based on the present disclosure.

FIG. 18 is a cross-sectional view of a module in a fifth embodiment based on the present disclosure.

FIG. 19 is a cross-sectional view of a module in a sixth embodiment based on the present disclosure.

FIG. 20 is a cross-sectional view of a module in a seventh embodiment based on the present disclosure.

FIG. 21 is a bottom view of the module in the seventh embodiment based on the present disclosure.

FIG. 22 is a cross-sectional view of a module in a first modification of the seventh embodiment based on the present disclosure.

FIG. 23 is a bottom view of the module in the first modification of the seventh embodiment based on the present disclosure.

FIG. 24 is a cross-sectional view of a module in a second modification of the seventh embodiment based on the present disclosure.

FIG. 25 is a bottom view of the module in the second modification of the seventh embodiment based on the present disclosure.

FIG. 26 is a cross-sectional view of a module in an eighth embodiment based on the present disclosure.

FIG. 27 is a cross-sectional view along the line XXVII-XXVII in FIG. 26.

FIG. 28 is a bottom view of the module in the eighth embodiment based on the present disclosure.

FIG. 29 is a cross-sectional view of a module in a modification of the eighth embodiment based on the present disclosure.

FIG. 30 is a cross-sectional view along the line XXX-XXX in FIG. 29.

FIG. 31 is a bottom view of the module in the modification of the eighth embodiment based on the present disclosure.

FIG. 32 is a first illustrative view of a method of manufacturing the module in the modification of the eighth embodiment based on the present disclosure.

FIG. 33 is a second illustrative view of the method of manufacturing the module in the modification of the eighth embodiment based on the present disclosure.

FIG. 34 is a third illustrative view of the method of manufacturing the module in the modification of the eighth embodiment based on the present disclosure.

FIG. 35 is a fourth illustrative view of the method of manufacturing the module in the modification of the eighth embodiment based on the present disclosure.

FIG. 36 is a fifth illustrative view of the method of manufacturing the module in the modification of the eighth embodiment based on the present disclosure.

FIG. 37 is a sixth illustrative view of the method of manufacturing the module in the modification of the eighth embodiment based on the present disclosure.

FIG. 38 is a seventh illustrative view of the method of manufacturing the module in the modification of the eighth embodiment based on the present disclosure.

FIG. 39 is a cross-sectional view of a module in a ninth embodiment based on the present disclosure.

FIG. 40 is a cross-sectional view along the line XL-XL in FIG. 39.

FIG. 41 is a bottom view of the module in the ninth embodiment based on the present disclosure.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

Though an example where some electronic components are mounted on a surface of a substrate is shown in an embodiment below, a type, a shape, the number, arrangement, and the like of the mounted electronic components are shown merely by way of example, and limitation thereto is not intended. Which one of a plurality of electronic components is defined as a “first . . . ” and which another one of the plurality of electronic components is defined as a “second . . . ” can be selected as appropriate, and setting is made each time for the sake of convenience of description. Therefore, a way of allocation of a component as a “first . . . ” may be different between embodiments even when embodiments are similar in construction to each other.

### First Embodiment

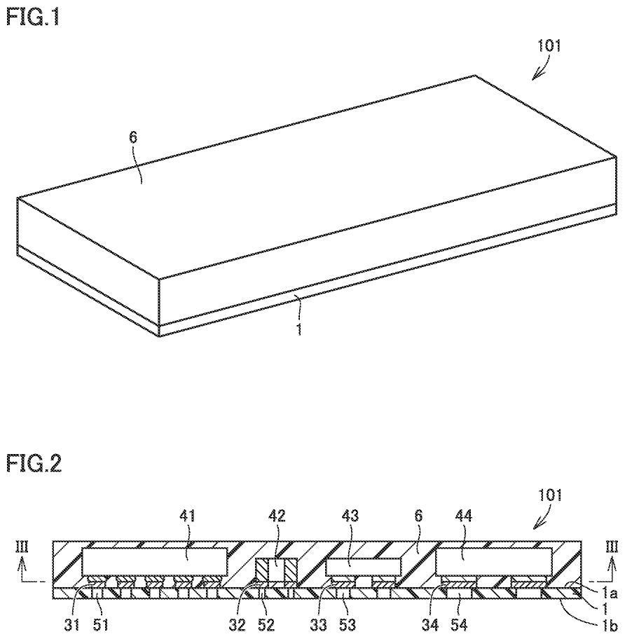

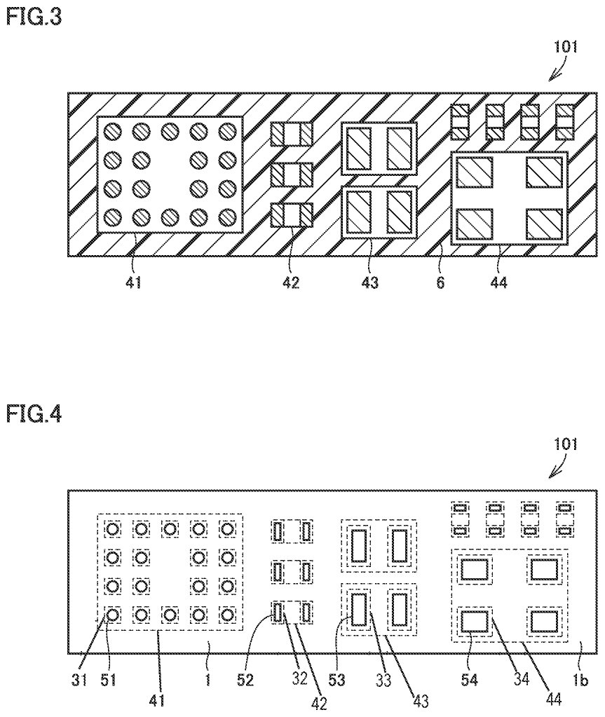

A module in a first embodiment based on the present disclosure will be described with reference to FIGS. 1 to 4. FIG. 1 shows an appearance of a module 101 in the present embodiment. FIG. 2 shows a cross-sectional view of module 101. FIG. 3 shows a cross-sectional view along the line III-III in FIG. 2. Exactly speaking, a cutting line along III-III passes through an electrode, and an outer geometry of an electronic component located thereon is hidden by a sealing resin and not viewable. For the sake of convenience of description, however, not only the electrode but also the outer geometry of the electronic component is shown with a solid line as being viewable. This is applicable also to each embodiment below. FIG. 4 shows a bottom view of module 101.

Module 101 in the present embodiment includes a substrate 1 including a first surface 1a, a first land electrode 31 arranged on first surface 1a, and a first electronic component 41 mounted on substrate 1 with first land electrode 31 being interposed. Substrate 1 is provided with a first opening 51 that passes through substrate 1 in a direction of thickness within a projection area of first land electrode 31.

In the example shown here, a second electronic component 42, a third electronic component 43, and a fourth electronic component 44 in addition to first electronic component 41 are also mounted on substrate 1. These electronic components and first surface 1a are covered with a sealing resin 6. Substrate 1 is provided with a second opening 52, a third opening 53, and a fourth opening 54 in addition to first opening 51. A second land electrode 32, a third land electrode 33, and a fourth land electrode 34 in addition to first land electrode 31 are arranged on first surface 1a of substrate 1. Substrate 1 includes a second surface 1b as a surface opposite to first surface 1a. Substrate 1 may be made from a resin sheet. Alternatively, substrate 1 may be made from a wiring board.

In the present embodiment, a conductive material applied at the time of mounting can be accommodated in first opening 51 and there is no overflow of the conductive material therearound. Therefore, short-circuiting between adjacent electrodes can be avoided. Therefore, this module can achieve suppression of short-circuiting in mounting thereof on a motherboard or the like and mounting can be performed in a stable manner.

### Second Embodiment

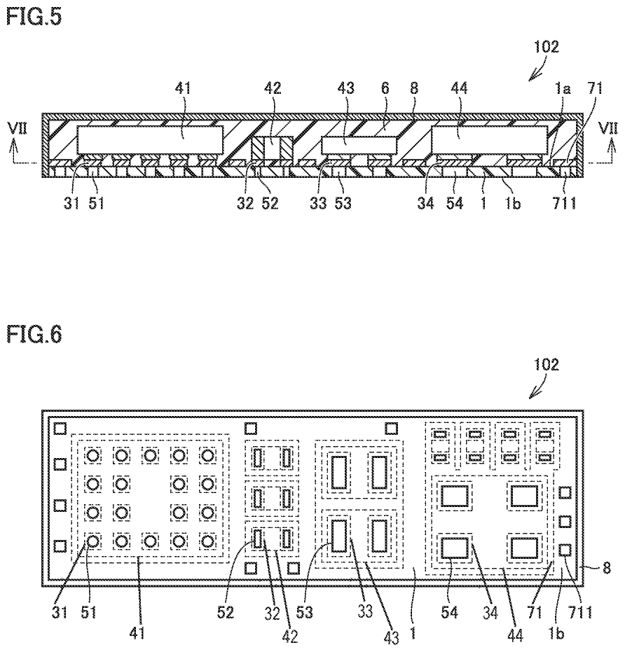

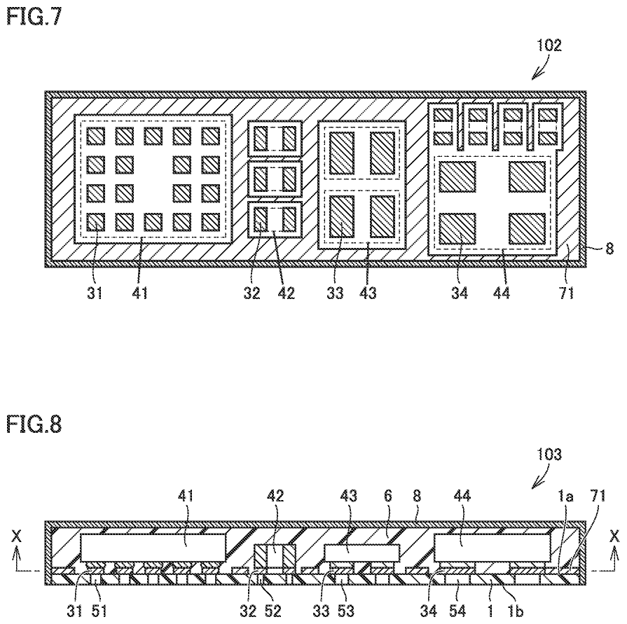

A module in a second embodiment based on the present disclosure will be described with reference to FIGS. 5 to 7. FIG. 5 shows a cross-sectional view of a module 102. FIG. 6 shows a bottom view of module 102. FIG. 7 shows a cross-sectional view along the line VII-VII in FIG. 5.

In module 102, first electronic component 41 is covered with sealing resin 6. A shield film 8 is arranged to cover at least a part of an outer surface of sealing resin 6. In the example shown here, an upper surface and a side surface of sealing resin 6 are covered with shield film 8. A first grounding electrode 71 electrically connected to shield film 8 is arranged on first surface 1a. Substrate 1 is provided with a first grounding opening 711 that passes through substrate 1 in the direction of thickness within a projection area of first grounding electrode 71.

In the example shown here, first grounding electrode 71 covers a most part of first surface 1a of substrate 1. First grounding electrode 71 extends also to an area between components mounted on first surface 1a of substrate 1. First grounding opening 711 is arranged in an outer peripheral portion of substrate 1.

The present embodiment can also obtain an effect as described in the first embodiment. Furthermore, in the present embodiment, first grounding electrode 71 connected to shield film 8 is provided and substrate 1 is provided with first grounding opening 711 within the projection area of first grounding electrode 71. Therefore, electrical connection for grounding of shield film 8 can be made through a conductive material such as solder arranged in first grounding opening 711. Solder applied at the time of mounting can be accommodated in first grounding opening 711 and there is no overflow of solder therearound. Therefore, short-circuiting between adjacent electrodes can be avoided. Therefore, this module can achieve suppression of short-circuiting in mounting thereof on a motherboard or the like and mounting can be performed in a stable manner.

(First Modification)

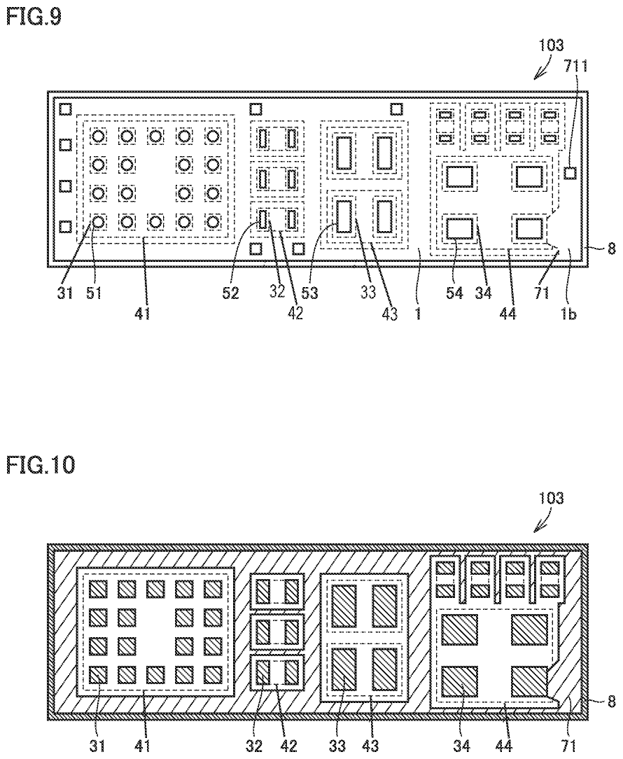

A module 103 as a first modification of the present embodiment will be described with reference to FIGS. 8 to 10. FIG. 8 shows a cross-sectional view of module 103. FIG. 9 shows a bottom view of module 103. FIG. 10 shows a cross-sectional view along the line X-X in FIG. 8. First grounding electrode 71 is thus connected to an electrode of a component mounted on first surface 1a. In the example shown here, among a plurality of electrodes provided in the components mounted on first surface 1a, there is an electrode for grounding, and first grounding electrode 71 is connected to such an electrode. In other words, a grounding electrode for a component and first grounding electrode 71 for shield film 8 are connected to each other.

(Second Modification)

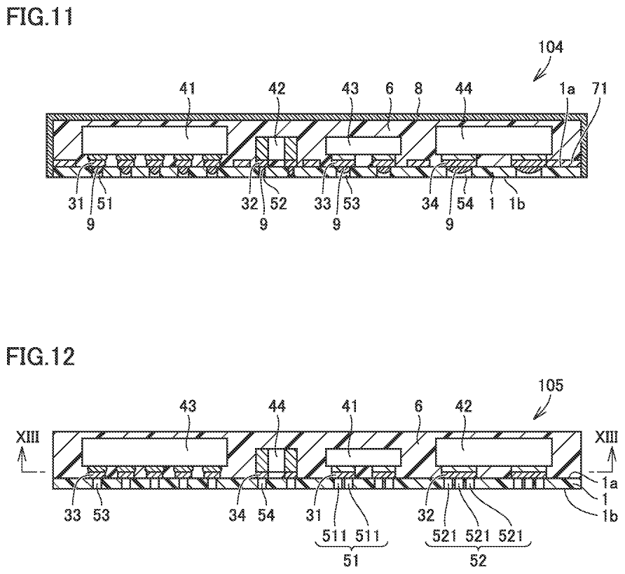

A module 104 as a second modification of the present embodiment will be described with reference to FIG. 11. FIG. 11 shows a cross-sectional view of module 104.

In module 104, a conductive material 9 is arranged in the inside of first opening 51. For example, solder may be adopted as conductive material 9. First opening 51 is not filled with conductive material 9. The entire conductive material 9 is not necessarily accommodated within a range of the thickness of substrate 1, and a part of conductive material 9 may extend off from first opening 51 in the direction of thickness of substrate 1.

### Third Embodiment

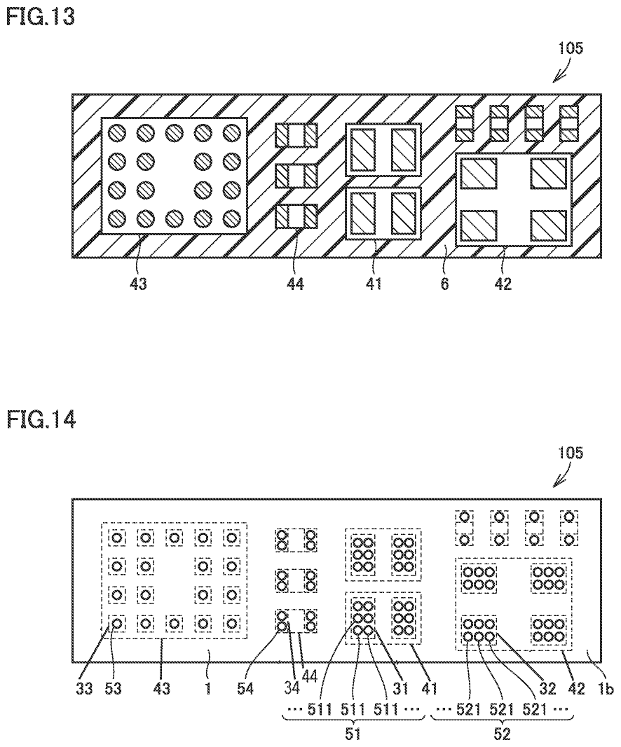

A module in a third embodiment based on the present disclosure will be described with reference to FIGS. 12 to 15. FIG. 12 shows a cross-sectional view of a module 105 in the present embodiment. FIG. 13 shows a cross-sectional view along the line XIII-XIII in FIG. 12. FIG. 14 shows a bottom view of module 105.

Module 105 is similar in basic construction to that described in the first embodiment. Module 105 is different from module 101 shown in the first embodiment in positions of first land electrode 31, first electronic component 41, and the like. First electronic component 41 is mounted on substrate 1 with first land electrode 31 being interposed. Substrate 1 is provided with first opening 51 that passes through substrate 1 in the direction of thickness within the projection area of first land electrode 31. First opening 51 is an assembly of a plurality of first opening elements 511.

In the present embodiment, second electronic component 42 is further mounted with second land electrode 32 being interposed. A second opening 52 that passes through substrate 1 in the direction of thickness is provided in a projection area of second land electrode 32. Second opening 52 is an assembly of a plurality of second opening elements 521.

FIG. 15 shows exemplary use of module 105. Module 105 is mounted on a motherboard 10. A plurality of electrodes 12 are provided on a surface of motherboard 10. Some of electrodes 12 are further divided into a plurality of electrode elements 121. The plurality of first opening elements 511 are connected to the plurality of electrode elements 121, respectively.

The present embodiment can also obtain an effect as described in the first embodiment. Furthermore, in the present embodiment, first opening 51 is the assembly of the plurality of first opening elements 511. Therefore, for example, in a projection area of a land electrode large in area, a large number of opening elements should only be arranged in accordance with that area. Equalization of sizes of opening elements and adjustment of the number of arranged opening elements can allow adaptation to land electrodes various in size. Since the sizes of the opening elements can be equal, working for providing holes for providing the opening elements is facilitated.

### Fourth Embodiment

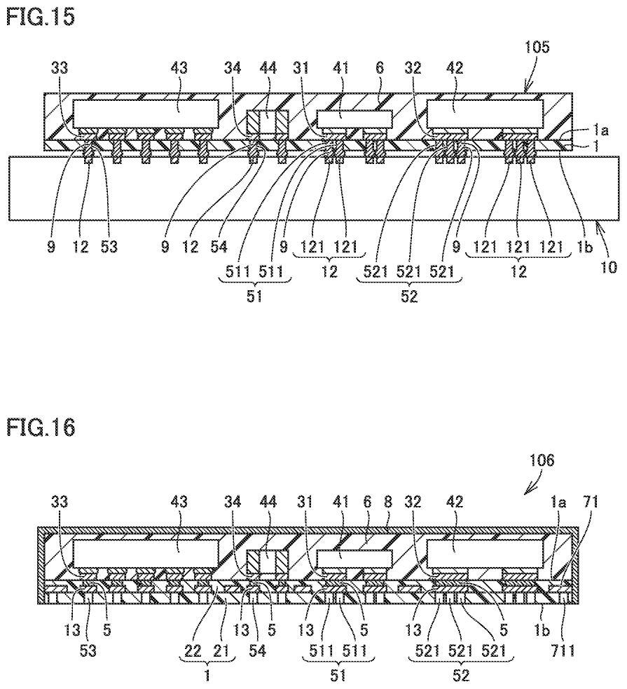

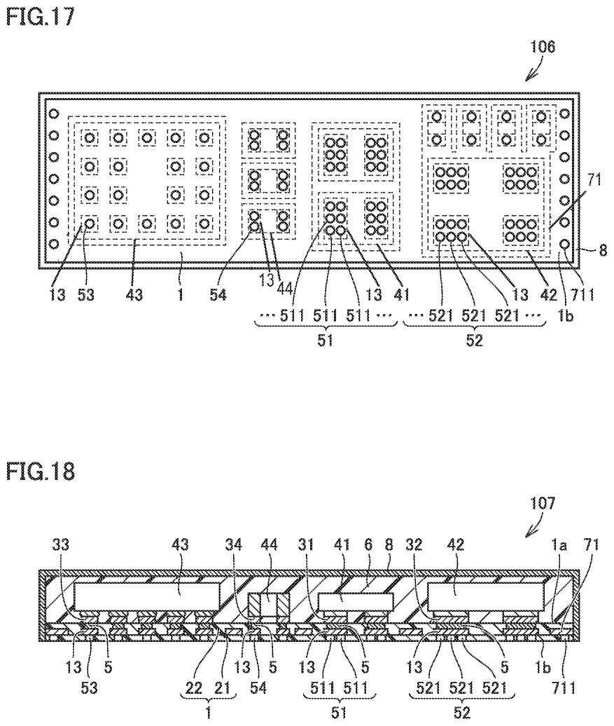

A module in a fourth embodiment based on the present disclosure will be described with reference to FIGS. 16 to 17. FIG. 16 shows a cross-sectional view of a module 106 in the present embodiment. FIG. 17 shows a bottom view of module 106.

Module 106 is in a two-layered structure including a first layer 21 and a second layer 22, and includes substrate 1 including first surface 1a as a surface of second layer 22 on a side far from first layer 21, first land electrode 31 arranged on first surface 1a, and first electronic component 41 mounted on substrate 1 with first land electrode 31 being interposed. An intermediate electrode 13 is arranged on an interface between first layer 21 and second layer 22. Intermediate electrode 13 and first land electrode 31 are electrically connected to each other by an interlayer connection conductor 5. First layer 21 is provided with first opening 51 that passes through first layer 21 in the direction of thickness within a projection area of intermediate electrode 13.

In the present embodiment, first opening 51 includes a plurality of first opening elements 511. Second opening 52 includes a plurality of second opening elements 521.

The present embodiment can also obtain an effect as described in the first embodiment. Furthermore, in the present embodiment, substrate 1 is in the two-layered structure and hence intermediate electrode 13 can be arranged on the interface between first layer 21 and second layer 22.

Preferably, in the present embodiment, first electronic component 41 is covered with sealing resin 6 and shield film 8 is arranged to cover at least a part of the outer surface of sealing resin 6. First grounding electrode 71 electrically connected to shield film 8 is arranged on the interface between first layer 21 and second layer 22. First layer 21 is provided with first grounding opening 711 that passes through first layer 21 in the direction of thickness within the projection area of first grounding electrode 71. Therefore, electrical connection for grounding of shield film 8 can be made through a conductive material such as solder arranged in first grounding opening 711.

### Fifth Embodiment

A module in a fifth embodiment based on the present disclosure will be described with reference to FIG. 18. FIG. 18 shows a cross-sectional view of a module 107 in the present embodiment. Though module 107 is similar in construction to module 106 shown in the fourth embodiment, first layer 21 is smaller in thickness than second layer 22. In other words, substrate 1 includes a plurality of layers and a thickness of a lowermost layer of the plurality of layers is smallest.

The present embodiment can also obtain an effect as described in the first embodiment. Furthermore, in the present embodiment, first layer 21 of the plurality of layers included in substrate 1 is smallest in thickness. Therefore, a volume of first opening 51 is small and an amount of solder necessary in mounting of this module can be suppressed.

### Sixth Embodiment

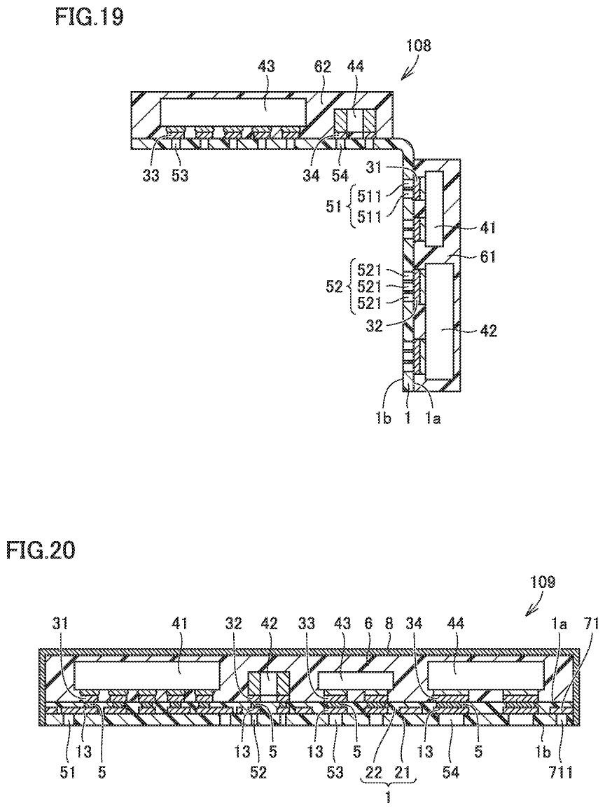

A module in a sixth embodiment based on the present disclosure will be described with reference to FIG. 19. FIG. 19 shows a cross-sectional view of a module 108 in the present embodiment. Though module 108 is similar in basic construction to module 105 shown in the fourth embodiment, the sealing resin is divided into two parts. Module 108 includes sealing resins 61 and 62 separate from each other. Substrate 1 is contiguous, and sealing resins 61 and 62 are formed at different positions on first surface 1a of substrate 1. In an intermediate portion of first surface 1a, there is a portion where neither of the sealing resins is placed, and with flexibility of substrate 1, module 108 can be bent at this portion.

The present embodiment can also obtain an effect as described in the first embodiment. Furthermore, in the present embodiment, the sealing resin is divided so that the entirety can be bent and consequently a degree of freedom in posture in mounting is enhanced. Though an example in which the sealing resin is divided into two parts is shown in the present embodiment, the sealing resin may be divided into at least three parts.

### Seventh Embodiment

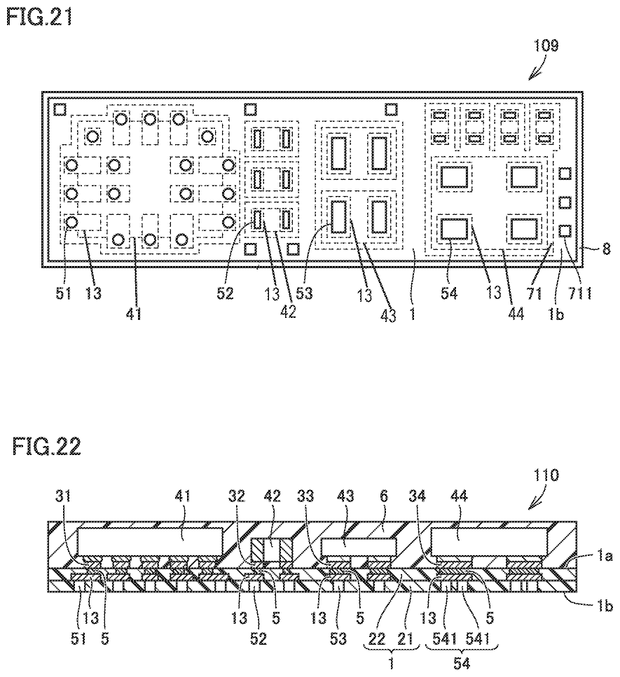

A module in a seventh embodiment based on the present disclosure will be described with reference to FIGS. 20 to 21. FIG. 20 shows a cross-sectional view of a module 109 in the present embodiment. FIG. 21 shows a bottom view of module 109. Module 109 is similar in basic construction to module 102 shown in the second embodiment. In the present embodiment, substrate 1 is in the two-layered structure including first layer 21 and second layer 22. Intermediate electrode 13 is arranged on the interface between first layer 21 and second layer 22.

In the present embodiment, intermediate electrode 13 extends to the outside of the projection area of first land electrode 31 and at least a part of first opening 51 is located outside the projection area of first land electrode 31.

The present embodiment can also obtain an effect as described in the first embodiment. Furthermore, in the present embodiment, intermediate electrode 13 extends to the outside of the projection area of first land electrode 31 and at least a part of first opening 51 is arranged outside the projection area of first land electrode 31. Therefore, first opening 51 can be arranged at a distance. Even when electrodes are densely arranged in first electronic component 41, first opening 51 can be arranged at a sufficient distance as being drawn outward. Therefore, short-circuiting in mounting on a motherboard or the like can be suppressed and mounting can be performed in a stable manner.

As shown in the present embodiment, preferably, intermediate electrode 13 extends to the outside of the projection area of first electronic component 41 and at least a part of first opening 51 is located outside the projection area of first electronic component 41. By adopting this construction, first opening 51 can be arranged at a sufficient distance as being drawn outward regardless of the size of first electronic component 41. Therefore, short-circuiting in mounting on a motherboard or the like can be suppressed and mounting can be performed in a stable manner.

(First Modification)

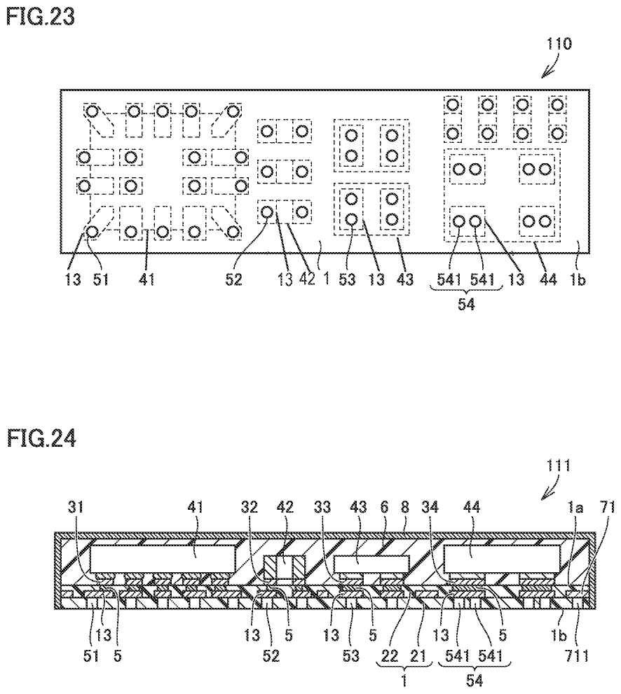

A first modification in the present embodiment will be described with reference to FIGS. 22 to 23. FIG. 22 shows a cross-sectional view of a module 110 as the first modification. FIG. 23 shows a bottom view of module 110. Such a construction may be applicable. By adopting this construction, openings can be uniform in size. In addition, since dense arrangement of openings can be avoided, module 110 can be mounted in a stable manner.

(Second Modification)

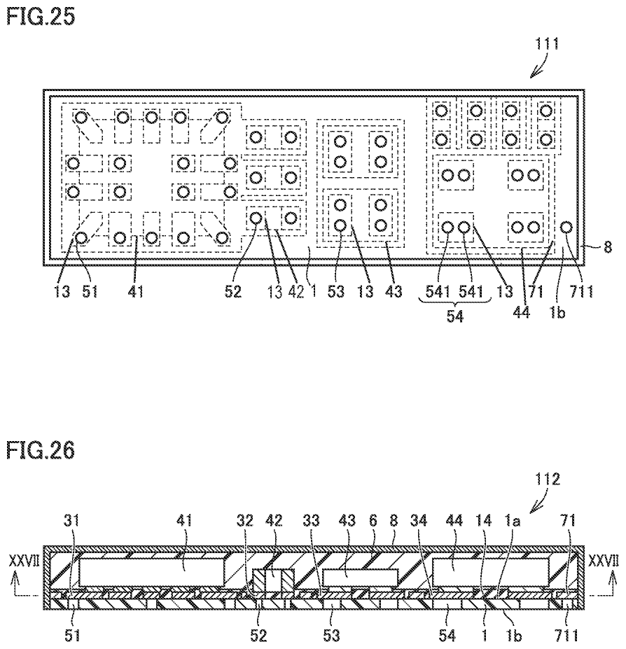

A second modification in the present embodiment will be described with reference to FIGS. 24 to 25. FIG. 24 shows a cross-sectional view of a module 111 as the second modification. FIG. 25 shows a bottom view of module 111. Such a construction may be applicable. In module 111, the upper surface and the side surface of sealing resin 6 are covered with shield film 8. First grounding electrode 71 is arranged to be connected to shield film 8. By adopting this construction, in module 111 including first grounding electrode 71 connected to shield film 8, module 111 can be mounted in a stable manner.

### Eighth Embodiment

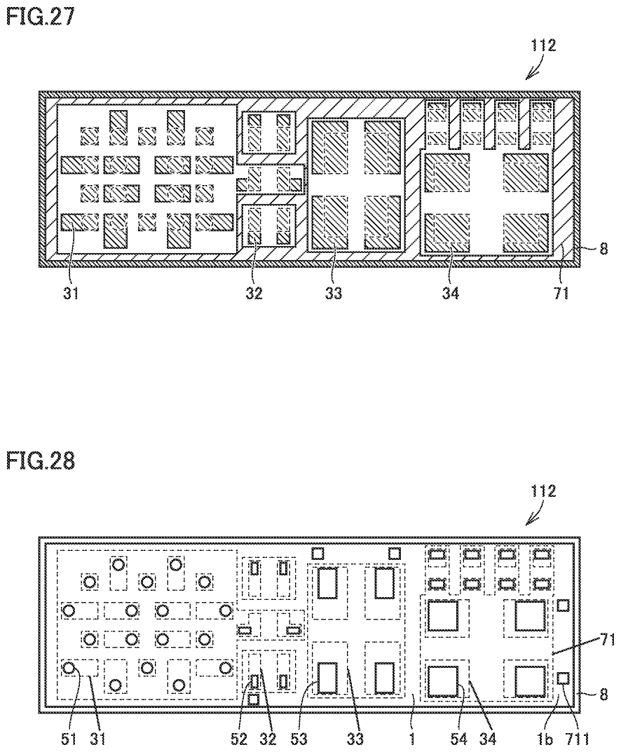

A module in an eighth embodiment based on the present disclosure will be described with reference to FIGS. 26 to 28. FIG. 26 shows a cross-sectional view of a module 112 in the present embodiment. FIG. 27 shows a cross-sectional view along the line XXVII-XXVII in FIG. 26. FIG. 28 shows a bottom view of module 112. Module 112 is similar in basic construction to module 102 shown in the second embodiment. In the present embodiment, however, first surface 1a of substrate 1 is covered with an insulating film 14. First grounding electrode 71 arranged on first surface 1a is also covered with insulating film 14.

In the present embodiment, insulating film 14 that partially covers first land electrode 31 is provided. First electronic component 41 is electrically connected to first land electrode 31 in an exposed area of first land electrode 31 that is exposed without being covered with insulating film 14.

The present embodiment can also obtain an effect as described in the first embodiment. Furthermore, in the present embodiment, insulating film 14 is arranged and first electronic component 41 is connected to first land electrode 31 in the exposed area. Therefore, the conductive material applied at the time of mounting is held back by insulating film 14 and less likely to flow out to a surrounding area. Therefore, this module can achieve more reliable suppression of short-circuiting in mounting thereof on a motherboard or the like and mounting can be performed in a stable manner.

(Modification)

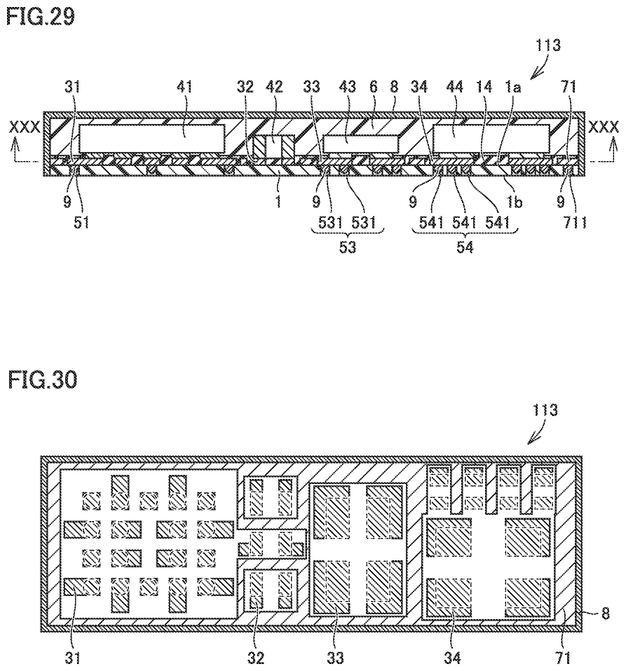

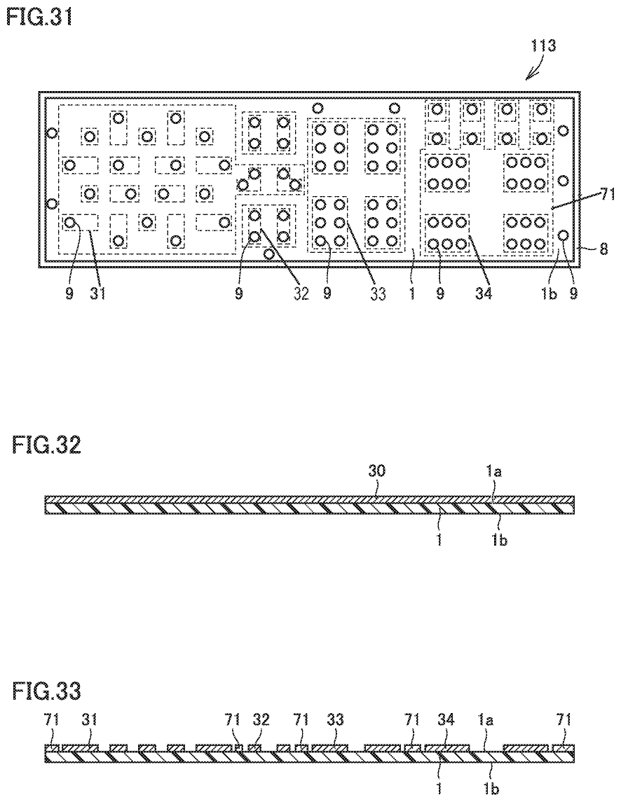

A modification in the present embodiment will be described with reference to FIGS. 29 to 31. FIG. 29 shows a cross-sectional view of a module 113. FIG. 30 shows a cross-sectional view along the line XXX-XXX in FIG. 29. FIG. 31 shows a bottom view of module 113. In module 113, conductive material 9 is arranged in the inside of first opening 51. Such a construction may be applicable.

(Manufacturing Method)

A method of manufacturing module 113 shown in FIGS. 29 to 31 will be described with reference to FIGS. 32 to 38.

Initially, substrate 1 is prepared as shown in FIG. 32. Substrate 1 includes first surface 1a and second surface 1b. First surface 1a is covered with a conductive film 30. Substrate 1 having one surface covered with conductive film 30 may be, for example, a resin sheet with a copper foil. Substrate 1 may be formed of resin.

Conductive film 30 is patterned. The construction shown in FIG. 33 is thus obtained. At this time point, a remaining part of conductive film 30 serves as a circuit. First land electrode 31, second land electrode 32, third land electrode 33, fourth land electrode 34, first grounding electrode 71, and the like are formed from the remaining part of conductive film 30.

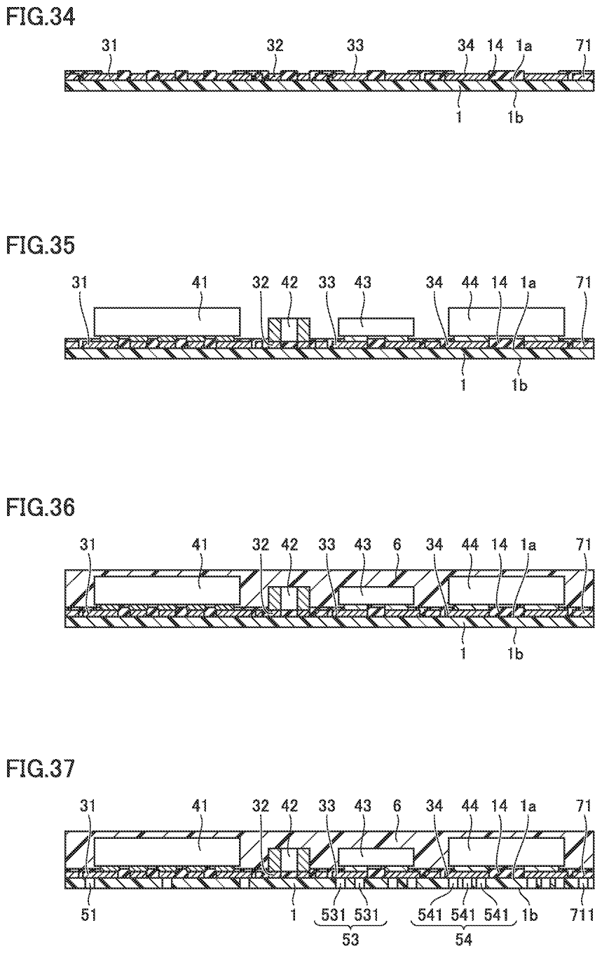

As shown in FIG. 34, insulating film 14 that covers the upper surface is formed. Insulating film 14 may be formed in such a manner that the entire surface is first covered therewith and thereafter an unnecessary part thereof is removed. Insulating film 14 may be, for example, a resist film. Some openings are provided in insulating film 14, and first land electrode 31, second land electrode 32, third land electrode 33, fourth land electrode 34, first grounding electrode 71, and the like are partially exposed through openings in insulating film 14.

As shown in FIG. 35, an electronic component is mounted. In the example shown here, first electronic component 41, second electronic component 42, third electronic component 43, and fourth electronic component 44 are mounted. First electronic component 41 is mounted on first land electrode 31. Second electronic component 42 is mounted on second land electrode 32. Third electronic component 43 is mounted on third land electrode 33. Fourth electronic component 44 is mounted on fourth land electrode 34.

As shown in FIG. 36, sealing resin 6 is formed. Sealing resin 6 is formed to cover insulating film 14, first electronic component 41, second electronic component 42, third electronic component 43, and fourth electronic component 44.

As shown in FIG. 37, hole boring is performed on substrate 1. Hole boring may be performed, for example, by laser processing. First opening 51 is provided to reach first land electrode 31. Second opening 52 is provided to reach second land electrode 32. Third opening 53 is provided to reach third land electrode 33. Fourth opening 54 is provided to reach fourth land electrode 34. Third opening 53 includes a plurality of third opening elements 531. Fourth opening 54 includes a plurality of fourth opening elements 541.

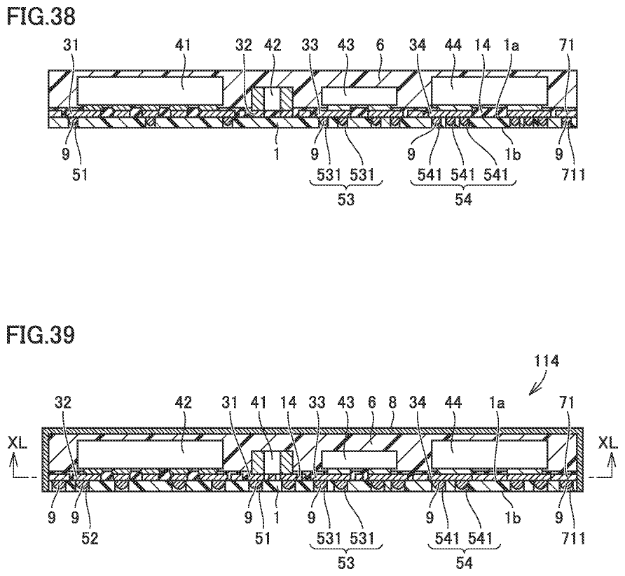

As shown in FIG. 38, conductive material 9 is arranged. Solder may be employed as conductive material 9. Conductive material 9 is arranged in the inside of first opening 51, second opening 52, third opening 53, fourth opening 54, and first grounding opening 711. Conductive material 9 can be arranged by printing.

Shield film 8 is formed to cover the upper surface and the side surface. Shield film 8 may be formed by sputtering. Module 113 shown in FIGS. 29 to 31 can thus be obtained.

### Ninth Embodiment

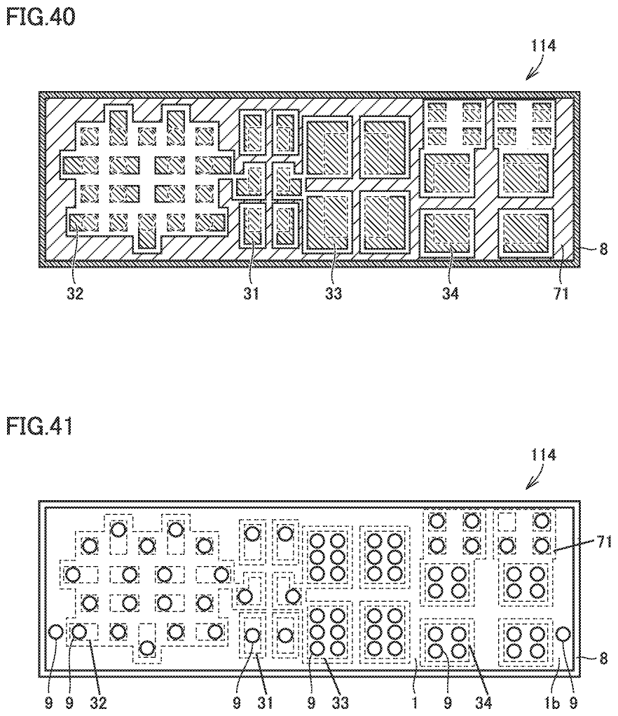

A module in a ninth embodiment based on the present disclosure will be described with reference to FIGS. 39 to 41. FIG. 39 shows a cross-sectional view of a module 114 in the present embodiment. FIG. 40 shows a cross-sectional view along the line XL-XL in FIG. 39. FIG. 41 shows a bottom view of module 114. Module 114 is similar in basic construction to module 113 shown in FIG. 29. Based on comparison with module 113, however, a position of first electronic component 41 is different.

In the present embodiment, first opening 51 is larger than the exposed area.

The present embodiment can also obtain an effect as described in the first embodiment. Furthermore, in the present embodiment, since first opening 51 is larger than the exposed area, in mounting of module 114, reliable connection can be achieved with the use of a sufficient amount of conductive material 9.

As shown in the present embodiment, preferably, first land electrode 31 extends to the outside of the projection area of first electronic component 41 and at least a part of first opening 51 is located outside the projection area of first electronic component 41. By adopting this construction, first opening 51 can be arranged at a sufficient distance as being drawn outward regardless of the size of first electronic component 41. Therefore, short-circuiting in mounting on a motherboard or the like can be suppressed and mounting can be performed in a stable manner.

A plurality of features in the embodiments above may be adopted as being combined as appropriate.

The embodiments disclosed herein are illustrative and non-restrictive in every respect. The scope of the present disclosure is defined by the terms of the claims and is intended to include any modifications within the scope and meaning equivalent to the terms of the claims.

1 substrate; 1a first surface; 1b second surface; 5 interlayer connection conductor; 6, 61, 62 sealing resin; 8 shield film; 9 conductive material; 10 motherboard; 12 electrode; 13 intermediate electrode; 14 insulating film; 21 first layer; 22 second layer; 30 conductive film; 31 first land electrode; 32 second land electrode; 33 third land electrode; 34 fourth land electrode; 41 first electronic component; 42 second electronic component; 43 third electronic component; 44 fourth electronic component; 51 first opening; 52 second opening; 53 third opening; 54 fourth opening; 71 first grounding electrode; 101, 102, 103, 104, 105, 106, 107, 108, 109, 110, 111, 112, 113, 114 module; 121 electrode element; 511 first opening element; 521 second opening element; 531 third opening element; 541 fourth opening element; 711 first grounding opening

1. A module comprising:
a substrate including a first surface;
a first land electrode arranged on the first surface;
a first electronic component mounted on the substrate with the first land electrode being interposed; and
an insulating film partially covering the first land electrode, wherein
the substrate is provided with a first opening passing through the substrate in a thickness direction of the substrate within a projection area of the first land electrode,
the first electronic component is electrically connected to the first land electrode in an exposed area in the first land electrode exposed without being covered with the insulating film, and
the first opening is larger than the exposed area.

2. The module according to claim 1, wherein
the first land electrode extends to outside of a projection area of the first electronic component, and at least a part of the first opening is located outside the projection area of the first electronic component.

3. The module according to claim 1, wherein
the first electronic component is covered with a sealing resin,
a shield film is arranged to cover at least a part of an outer surface of the sealing resin, and
a first grounding electrode electrically connected to the shield film is arranged on the first surface, and the substrate is provided with a first grounding opening passing through the substrate in the thickness direction within a projection area of the first grounding electrode.

4. A module comprising:
a substrate in a two-layered structure including a first layer and a second layer, the substrate including a first surface as a surface of the second layer on a side farther from the first layer;
a first land electrode arranged on the first surface; and
a first electronic component mounted on the substrate with the first land electrode being interposed, wherein
an intermediate electrode is arranged on an interface between the first layer and the second layer,
the intermediate electrode and the first land electrode are electrically connected to each other by an interlayer connection conductor, and
the first layer is provided with a first opening passing through the first layer in a thickness direction of the first layer in a projection area of the intermediate electrode.

5. The module according to claim 4, wherein
the intermediate electrode extends to outside of a projection area of the first land electrode, and at least a part of the first opening is located outside the projection area of the first land electrode.

6. The module according to claim 4, wherein
the intermediate electrode extends to outside of a projection area of the first electronic component, and at least a part of the first opening is located outside the projection area of the first electronic component.

7. The module according to claim 4, wherein
the first electronic component is covered with a sealing resin,
a shield film is arranged to cover at least a part of an outer surface of the sealing resin, and
a first grounding electrode electrically connected to the shield film is arranged on an interface between the first layer and the second layer, and the first layer is provided with a first grounding opening passing through the first layer in the thickness direction within a projection area of the first grounding electrode.

8. The module according to claim 1, wherein
a conductive material is arranged in inside of the first opening.

9. The module according to claim 1, wherein
the first opening is an assembly of a plurality of first opening elements.

10. The module according to claim 2, wherein
the first electronic component is covered with a sealing resin,
a shield film is arranged to cover at least a part of an outer surface of the sealing resin, and
a first grounding electrode electrically connected to the shield film is arranged on the first surface, and the substrate is provided with a first grounding opening passing through the substrate in the thickness direction within a projection area of the first grounding electrode.

11. The module according to claim 5, wherein
the intermediate electrode extends to outside of a projection area of the first electronic component, and at least a part of the first opening is located outside the projection area of the first electronic component.

12. The module according to claim 5, wherein
the first electronic component is covered with a sealing resin,
a shield film is arranged to cover at least a part of an outer surface of the sealing resin, and
a first grounding electrode electrically connected to the shield film is arranged on an interface between the first layer and the second layer, and the first layer is provided with a first grounding opening passing through the first layer in the thickness direction within a projection area of the first grounding electrode.

13. The module according to claim 6, wherein
the first electronic component is covered with a sealing resin,
a shield film is arranged to cover at least a part of an outer surface of the sealing resin, and
a first grounding electrode electrically connected to the shield film is arranged on an interface between the first layer and the second layer, and the first layer is provided with a first grounding opening passing through the first layer in the thickness direction within a projection area of the first grounding electrode.

14. The module according to claim 2 wherein
a conductive material is arranged in inside of the first opening.

15. The module according to claim 3, wherein
a conductive material is arranged in inside of the first opening.

16. The module according to claim 4, wherein
a conductive material is arranged in inside of the first opening.

17. The module according to claim 5, wherein
a conductive material is arranged in inside of the first opening.

18. The module according to claim 6, wherein
a conductive material is arranged in inside of the first opening.

19. The module according to claim 7, wherein
a conductive material is arranged in inside of the first opening.

20. The module according to claim 2, wherein
the first opening is an assembly of a plurality of first opening elements.
